(19) United States
(12) Patent Application Publication
(10) Pub. No.: US 2025/0246990 A1
(43) Pub. Date: Jul. 31, 2025

(54) SEMICONDUCTOR DEVICE

(71) Applicant: Mitsubishi Electric Corporation, Tokyo (JP)

(72) Inventor: Teruaki NAGAHARA, Tokyo (JP)

(73) Assignee: Mitsubishi Electric Corporation, Tokyo (JP)

(21) Appl. No.: 18/942,341

(22) Filed: Nov. 8, 2024

(30) Foreign Application Priority Data
Jan. 26, 2024 (JP) 2024-010112

(51) Int. Cl. H02M 1/088; H03K 17/687

(52) U.S. Cl. CPC H02M 1/088; H03K 17/6872

(57) ABSTRACT

A semiconductor device includes: a second semiconductor element connected in parallel to a first semiconductor element; a source semiconductor element; a sink semiconductor element; a gate terminal of the first semiconductor element; a source-sink connection semiconductor element connected to a gate terminal of the second semiconductor element; and a control circuit for controlling on/off state transition of the source semiconductor element, the sink semiconductor element, and the source-sink connection semiconductor element so as to transition the first semiconductor element and the second semiconductor element to an on state in this order and transition the second semiconductor element and the first semiconductor element to an off state in this order.

### BACKGROUND OF THE INVENTION

### Field of the Invention

The technique disclosed in the present specification relates to a semiconductor device.

### Description of the Background Art

Conventionally, as a power element such as an inverter apparatus for driving a motor, an insulated gate bipolar transistor (IGBT) or a metal oxide semiconductor field effect transistor (MOSFET) made of inexpensive silicon (Si) is generally used.

On the other hand, in recent years, high-efficiency power elements made of silicon carbide (SiC) or gallium nitride (GaN), which are wide band gap semiconductors, have been increasingly used. Here, the wide band gap semiconductor generally refers to a semiconductor having a bandgap of about 2 eV or more, and a group 3 nitride such as gallium nitride (GaN), a group 2 oxide such as zinc oxide (ZnO), a group 2 chalcogenide such as zinc selenide (ZnSe), diamond, silicon carbide, and the like are known.

However, since a wide band gap semiconductor is expensive, the wide band gap semiconductor is not widely used in consumer devices and the like that place importance on cost. Therefore, it has been proposed to use a parallel circuit configured by connecting a small-size SiC-MOSFET and a Si-IGBT in parallel in a product for use with a long use time at a low current, such as a drive motor of a compressor of a domestic air conditioner (see, for example, Japanese Patent No. 6919292). According to such a product, cost reduction due to the small size of the SiC-MOSFET and improvement of efficiency (that is, reduction of loss) due to favorable DC characteristics at the time of low current of the SiC-MOSFET are expected.

In order to achieve both improvement in efficiency and cost reduction, it is necessary to reduce the element size of the SiC-MOSFET. However, when the element size of the SiC-MOSFET decreases, the amount of current that can flow (allowable current amount) decreases. Therefore, it is necessary to perform control in an appropriate order so that not only the SiC-MOSFET is in the on state in the gate drive circuit so that a large current does not flow only to the SiC-MOSFET to cause breakdown.

On the other hand, for the above control, a gate drive circuit of each element and a logic circuit for controlling the on/off state transition of each element at an individual timing are required, and there is a concern that the circuit scale may increase, and there is a concern that the timing control of the on/off state transition becomes complicated, thereby causing a malfunction of the system.

### SUMMARY

The technique disclosed in the present specification is a technique for controlling on/off state transition of a semiconductor element with a simple configuration and suppressing destruction of the semiconductor element.

A semiconductor device according to a first aspect of the technique disclosed in the present specification includes: a first semiconductor element; a second semiconductor element connected in parallel to the first semiconductor element; a first source semiconductor element connected between a first power supply potential and a gate terminal of the first semiconductor element; a first sink semiconductor element connected between a reference potential and a gate terminal of the second semiconductor element; a source-sink connection semiconductor element connected between the gate terminal of the first semiconductor element and the gate terminal of the second semiconductor element; and a control circuit for controlling on/off state transition of the first source semiconductor element, the first sink semiconductor element, and the source-sink connection semiconductor element so as to transition the first semiconductor element and the second semiconductor element to an on state in this order and transition the second semiconductor element and the first semiconductor element to an off state in this order.

According to at least the first aspect of the technique disclosed in the present specification, the transition of the on/off state of each semiconductor element can be controlled by a simple circuit configuration including the source-sink connection semiconductor element, and destruction of the semiconductor element can be suppressed.

Further, objects, features, aspects, and advantages relating to the technique disclosed in the present specification will be more apparent from the following detailed description and the accompanying drawings.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a diagram illustrating an example of an operation of a Si element and an operation of a SiC element;

FIG. 2 is a diagram illustrating an example of a drive circuit for driving the Si element and the SiC element;

FIG. 3 is a diagram conceptually illustrating an example of a circuit configuration of a semiconductor device according to a preferred embodiment;

FIG. 4 is a diagram illustrating an example of the operation of the Si element and the operation of the SiC element according to the preferred embodiment;

FIG. 5 is a diagram conceptually illustrating an example of a circuit configuration of a semiconductor device according to the preferred embodiment;

FIG. 6 is a diagram illustrating an example of an increase in a gate voltage of a SiC-MOSFET and a decrease in a gate-source voltage VGS of a source-sink connection MOSFET;

FIG. 7 is a diagram conceptually illustrating a modification of a circuit configuration of a semiconductor device according to the preferred embodiment;

FIG. 8 is a diagram conceptually illustrating an example of a circuit configuration of a semiconductor device according to the preferred embodiment;

FIG. 9 is a diagram conceptually illustrating an example of a circuit configuration of a semiconductor device according to the preferred embodiment;

FIG. 10 is a diagram illustrating an example of the operation of the Si element and the operation of the SiC element according to the preferred embodiment;

FIG. 11 is a diagram conceptually illustrating an example of a circuit configuration of a semiconductor device according to the preferred embodiment;

FIG. 12 is a diagram illustrating an example of the operation of the Si element and the operation of the SiC element according to the preferred embodiment;

FIG. 13 is a diagram conceptually illustrating an example of a circuit configuration of a semiconductor device according to the preferred embodiment;

FIG. 14 is a diagram conceptually illustrating an example of a circuit configuration of a semiconductor device according to the preferred embodiment;

FIG. 15 is a diagram illustrating an example of DC characteristics of a MOSFET;

FIG. 16 is a diagram conceptually illustrating an example of a circuit configuration of a semiconductor device according to the preferred embodiment;

FIG. 17 is a diagram illustrating an example of operation of the Si-IGBT and the SiC-MOSFET;

FIG. 18 is a diagram illustrating an example of a drive circuit having a general parallel connection circuit;

FIG. 19 is a diagram conceptually illustrating an example of a circuit configuration of a semiconductor device according to the preferred embodiment;

FIG. 20 is a diagram illustrating an example of the operation of the Si element and the operation of the SiC element according to the preferred embodiment;

FIG. 21 is a diagram illustrating an example of a configuration in which a gate of the SiC-MOSFET and the sink MOSFET are connected via a sink diode; and

FIG. 22 is a diagram illustrating an example of the operation of the Si element and the operation of the SiC element according to the preferred embodiment.

### DESCRIPTION OF THE PREFERRED EMBODIMENTS

Hereinafter, preferred embodiments will be described with reference to the accompanying drawings. In the following preferred embodiments, detailed features and the like are also shown for the description of the technique, but they are merely examples, and not all of them are necessarily essential features in order to enable the preferred embodiments to be carried out.

Note that the drawings are schematically illustrated, and omission of a configuration, simplification of a configuration, or the like is appropriately made in the drawings for convenience of description. In addition, the mutual relationship of sizes and positions of configurations and the like illustrated in different drawings is not necessarily accurately described, and can be appropriately changed. In addition, hatching may be applied to a drawing such as a plan view that is not a cross-sectional view in order to facilitate understanding of the contents of the preferred embodiment.

Furthermore, in the following description, similar constituent elements are denoted by the same reference numerals, and names and functions thereof are also similar. Therefore, detailed description thereof may be omitted in order to avoid duplication.

In addition, in the description described in the present specification, when a certain component is described as being “provided”, “comprised”, “included”, or the like, the expression is not an exclusive expression excluding the presence of other components unless otherwise specified.

In addition, in the description described in the present specification, even if ordinal numbers such as “first” or “second” are used, these terms are used for convenience to facilitate understanding of the contents of the preferred embodiments, and the contents of the preferred embodiments are not limited to the order or the like that can be caused by these ordinal numbers.

### First Preferred Embodiment

Hereinafter, a semiconductor device according to the present preferred embodiment will be described. For convenience of description, first, a configuration of a semiconductor device known by the inventor will be described.

In order to achieve both improvement in efficiency and cost reduction, it is necessary to reduce the element size of the SiC-MOSFET. In this case, when the element size of the SiC-MOSFET decreases, the current that can flow decreases. Therefore, it is necessary to perform control in an appropriate order so that not only the SiC-MOSFET is in the on state in the gate drive circuit so that a large current does not flow only to the SiC-MOSFET to cause breakdown.

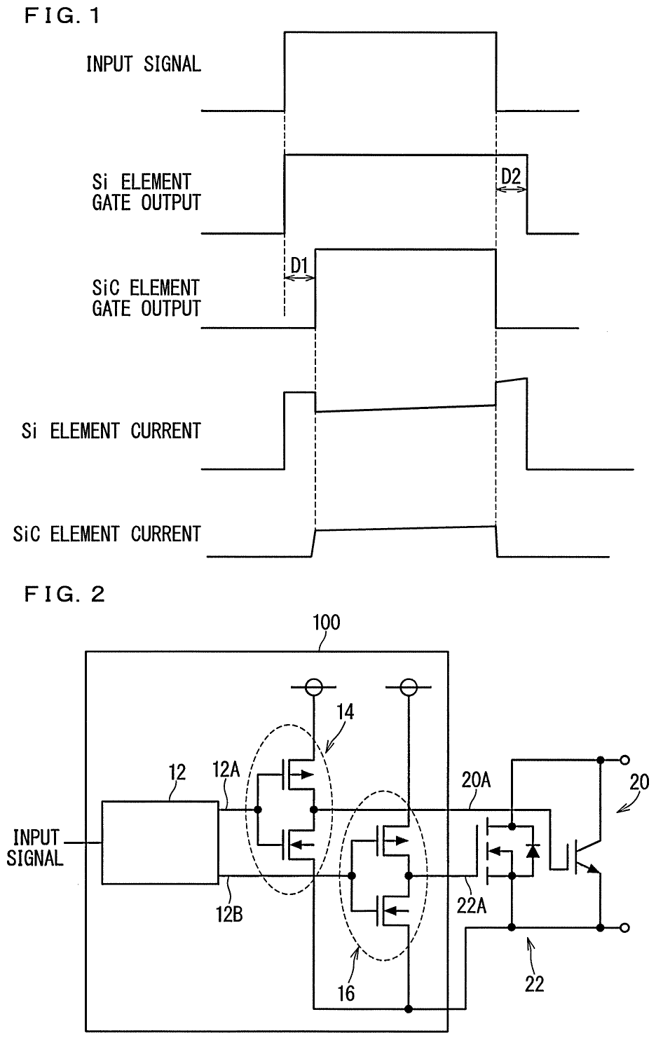

FIG. 1 is a diagram illustrating an example of an operation of a Si element and an operation of a SiC element.

As illustrated in FIG. 1, the rise of the gate output of the SiC element with respect to the input signal is delayed by time D1 with respect to the gate output of the Si element in consideration of the timing (rising time) at which the Si element transitions to the on state. In addition, the fall of the gate output of the Si element is delayed by time D2 with respect to the gate output of the SiC element in consideration of the timing (fall time) at which the SiC element transitions to the off state.

Along with this, the current in the Si element corresponds to the total current immediately after the rise, and then decreases by being divided into the SiC element that rises with a delay according to the characteristics of the element, and further corresponds to the total current again after the fall of the SiC element.

For such control, a gate drive circuit of each element and a logic circuit for controlling on/off of each element at individual timing are required.

FIG. 2 is a diagram illustrating an example of a drive circuit for driving the Si element and the SiC element. As illustrated in FIG. 2, the drive circuit 100 includes a control signal generation circuit 12 that receives an input signal, a gate drive circuit 14 to which the control signal 12A is input from the control signal generation circuit 12, and a gate drive circuit 16 to which the control signal 12B is input from the control signal generation circuit 12. The Si-IGBT 20 to which a gate signal is input from the gate drive circuit 14 to the gate terminal 20A and the SiC-MOSFET 22 to which a gate signal is input from the gate drive circuit 16 to the gate terminal 22A are connected to the drive circuit 100.

When the circuit structure as illustrated in FIG. 2 is adopted, the circuit scale increases, and the timing control of the on/off state transition becomes complicated, so that there is a concern of malfunction of the system.

### <Configuration of Semiconductor Device>

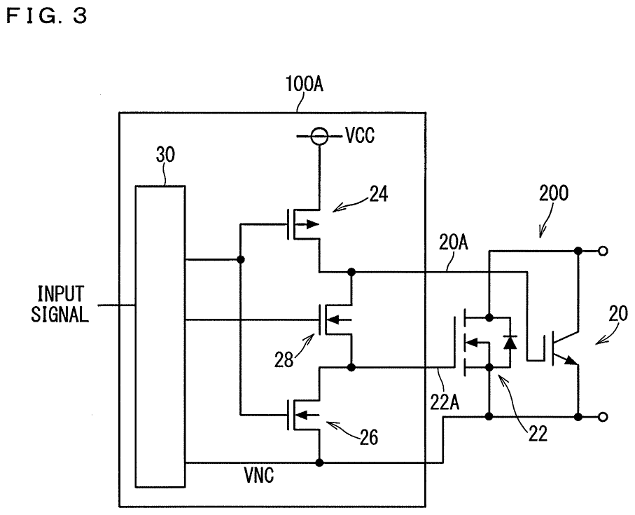

FIG. 3 is a diagram conceptually illustrating an example of a circuit configuration of a semiconductor device according to the present preferred embodiment. As illustrated in FIG. 3, the drive circuit 100A in the semiconductor device includes: a source MOSFET 24 connected between a gate terminal 20A for on/off control of a Si-IGBT 20 (hereinafter also referred to as a Si element) as a first semiconductor element and a potential VCC; a sink MOSFET 26 connected between a reference potential VNC and a gate terminal 22A for on/off control of a SiC-MOSFET 22 (hereinafter also referred to as a SiC element) as a second semiconductor element having lower current capability than the first semiconductor element; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a control circuit 30 that causes these MOSFETs (source MOSFET 24, sink MOSFET 26, and source-sink connection MOSFET 28) to make on/off state transitions in a predetermined order. The parallel connection circuit 200 is connected to the drive circuit 100A. The parallel connection circuit 200 is a circuit in which a Si-IGBT 20 as a first semiconductor element and a SiC-MOSFET 22 as a second semiconductor element having a lower current capability than the first semiconductor element are connected in parallel.

In the parallel connection circuit 200, the collector terminal of the Si-IGBT 20 and the drain terminal of the SiC-MOSFET 22 are connected, and the emitter terminal of the Si-IGBT 20 and the source terminal of the SiC-MOSFET 22 are connected.

The control circuit 30 is commonly connected to the gate terminal 24A of the source MOSFET 24 and the gate terminal 26A of the sink MOSFET 26, and is connected to the gate terminal 28A of the source-sink connection MOSFET 28 and the reference potential VNC.

In the on operation (transition to the on state) according to a control signal (input signal) from an external controller (not illustrated here) of the semiconductor device, in order to prevent all currents from flowing to the SiC element having a small size and being destroyed, it is necessary to first turn on the Si element capable of flowing a large current and turn on the SiC element having a small size with a predetermined time delay. On the contrary, the SiC element needs to be turned off first in the off operation (transition to the off state) by the control signal (input signal) from the external controller (not illustrated here) of the semiconductor device. Hereinafter, a detailed procedure will be described.

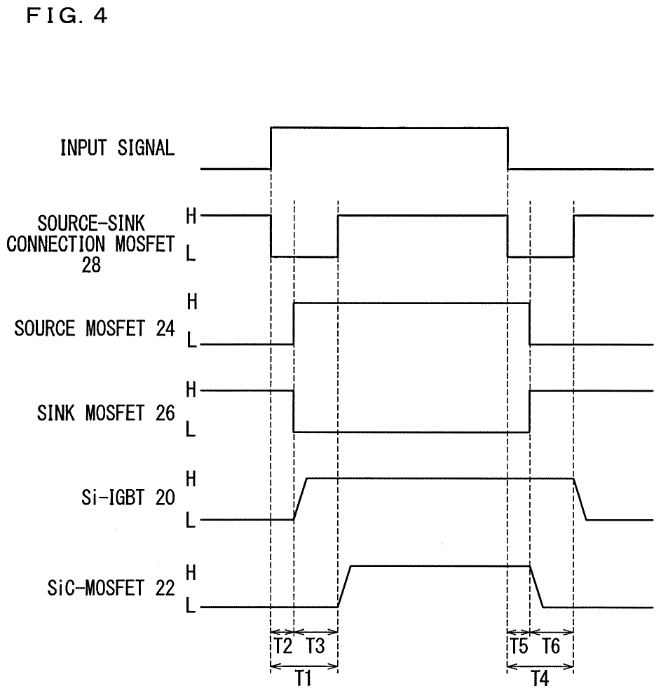

FIG. 4 is a diagram illustrating an example of the operation of the Si element and the operation of the SiC element according to the preferred embodiment.

As illustrated in FIG. 4, when an input signal (on signal) related to on operation is input to the control circuit 30, the control circuit 30 inputs an L-level signal to the gate terminal 28A of the source-sink connection MOSFET 28 for a predetermined time (time T1) to turn off the source-sink connection MOSFET 28, thereby disconnecting the connection between the gate terminal 20A for on/off control of the Si-IGBT 20 and the gate terminal 22A for on/off control of the SiC-MOSFET 22. The timing at which the L-level signal is input to the gate terminal 28A of the source-sink connection MOSFET 28 may be at the time of edge detection of the rise of the input signal (on signal).

Thereafter, the source MOSFET 24 and the sink MOSFET 26 whose gate inputs are coordinated perform transition operations opposite to each other. That is, in the source MOSFET 24, the signal input to the gate terminal 24A of the source MOSFET 24 changes from the L-level signal to the H-level signal, so that the off operation transitions to the on operation with a delay of time T2, and in the sink MOSFET 26, the signal input to the gate terminal 26A of the sink MOSFET 26 changes from the H-level signal to the L-level signal, so that the on operation transitions to the off operation with a delay of time T2.

As a result, the gate of the Si-IGBT 20 is charged, and the Si-IGBT 20 is turned on before the SiC-MOSFET 22. On the other hand, since the source-sink connection MOSFET 28 is turned off, the gate of the SiC-MOSFET 22 is disconnected from the gate of the Si-IGBT 20 and is not charged.

Thereafter, when the H level signal is input to the gate terminal 28A of the source-sink connection MOSFET 28 to turn on the source-sink connection MOSFET 28, the gate terminal 20A for on/off control of the Si-IGBT 20 and the gate terminal 22A for on/off control of the SiC-MOSFET 22 are connected. Then, charging of the gate of the SiC-MOSFET 22 is started, and the SiC-MOSFET 22 is turned on later than the Si-IGBT 20 by the time T3.

Next, when an input signal (off signal) related to an off operation is input to the control circuit 30, the control circuit 30 inputs an L-level signal to the gate terminal 28A of the source-sink connection MOSFET 28 for a predetermined time (time T4) to turn off the source-sink connection MOSFET 28, thereby disconnecting the connection between the gate terminal 20A for on/off control of the Si-IGBT 20 and the gate terminal 22A for on/off control of the SiC-MOSFET 22. The timing at which the L-level signal is input to the gate terminal 28A of the source-sink connection MOSFET 28 may be at the time of edge detection of the fall of the input signal (off signal).

Thereafter, the source MOSFET 24 and the sink MOSFET 26 whose gate inputs are coordinated perform transition operations opposite to each other. That is, in the source MOSFET 24, the signal input to the gate terminal 24A of the source MOSFET 24 changes from the H-level signal to the L-level signal, so that the source MOSFET transitions from the on-operation to the off-operation with a delay of time T5, and in the sink MOSFET 26, the signal input to the gate terminal 26A of the sink MOSFET 26 changes from the L-level signal to the H-level signal, so that the source MOSFET transitions from the off-operation to the on-operation with a delay of time T5.

As a result, the gate of the SiC-MOSFET 22 is discharged, and the SiC-MOSFET 22 is turned off before the Si-IGBT 20. On the other hand, since the source-sink connection MOSFET 28 is turned off, the gate of the Si-IGBT 20 is disconnected from the gate of the SiC-MOSFET 22 and is not discharged.

Thereafter, when the H level signal is input to the gate terminal 28A of the source-sink connection MOSFET 28 to turn on the source-sink connection MOSFET 28, the gate terminal 20A for on/off control of the Si-IGBT 20 and the gate terminal 22A for on/off control of the SiC-MOSFET 22 are connected. Then, the discharge of the gate of the Si-IGBT 20 is started, and the Si-IGBT 20 is turned off later than the SiC-MOSFET 22 by the time T6.

According to the above, the transition of the on/off state of each of the Si element and the SiC element can be controlled with a simpler circuit configuration. Specifically, it is possible to perform control to cause a delay in the on/off operation of the Si element and the SiC element with a simple circuit configuration without providing a gate drive circuit for causing a delay in the on/off operation for each of the Si element and the SiC element.

### Second Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### <Configuration of Semiconductor Device>

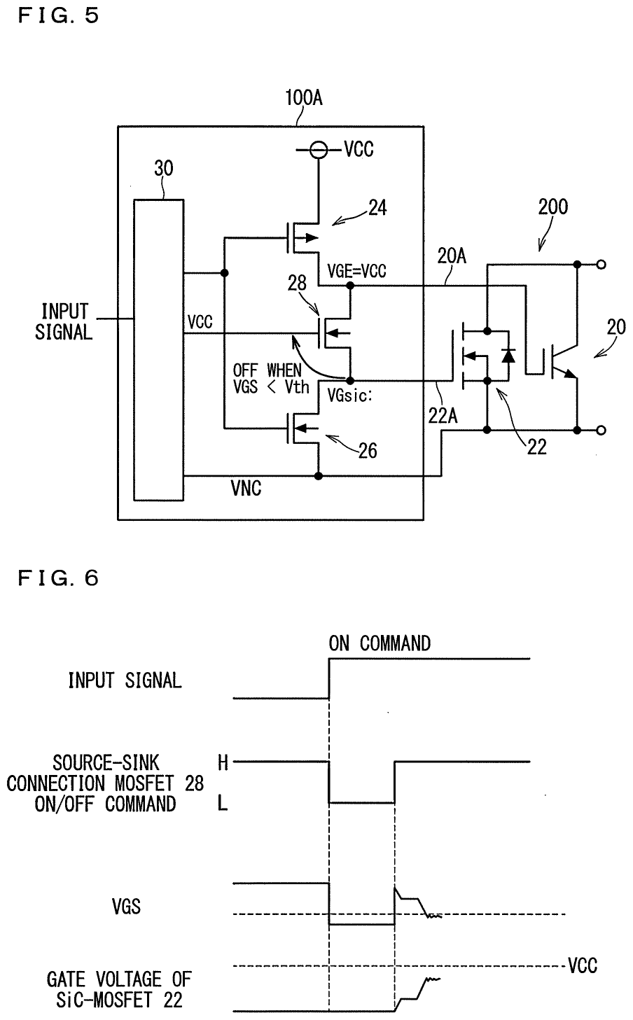

FIG. 5 is a diagram conceptually illustrating an example of a circuit configuration of a semiconductor device according to the present preferred embodiment. As illustrated in FIG. 5, the drive circuit 100A in the semiconductor device includes: a source MOSFET 24 connected between a gate terminal 20A for on/off control of the Si element and a potential VCC; a sink MOSFET 26 connected between a gate terminal 22A for on/off control of the SiC element and a reference potential VNC; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a control circuit 30 that causes these MOSFETs (source MOSFET 24, sink MOSFET 26, and source-sink connection MOSFET 28) to make on/off state transitions in a predetermined order. The parallel connection circuit 200 is connected to the drive circuit 100A.

In the configuration illustrated in FIG. 5, when an N-channel MOSFET is applied to the source-sink connection MOSFET 28, the control circuit 30 causes the source-sink connection MOSFET 28 to transition to the on state in order to charge the gate of the SiC-MOSFET 22.

At this time, the power supply voltage applied to the gate of the source-sink connection MOSFET 28 to transition the source-sink connection MOSFET 28 to the on state becomes the potential VCC. Since the potential VCC is equivalent to the gate voltage of the Si-IGBT 20, when the gate voltage of the SiC-MOSFET 22 increases by transitioning the source-sink connection MOSFET 28 to the on state, the gate-source voltage VGS of the source-sink connection MOSFET 28 decreases as the gate voltage of the SiC-MOSFET 22 increases. Since the gate-source voltage VGS needs to be equal to or higher than the gate threshold value Vth in order for the MOSFET to transition to the on state, in this case, the source-sink connection MOSFET 28 transitions to the off state before the gate voltage of the SiC-MOSFET 22 reaches the potential VCC.

FIG. 6 is a diagram illustrating an example of an increase in the gate voltage of the SiC-MOSFET 22 and a decrease in the gate-source voltage VGS of the source-sink connection MOSFET 28. As illustrated in FIG. 6, when the gate-source voltage VGS of the source-sink connection MOSFET 28 falls below the gate threshold value Vth, the source-sink connection MOSFET 28 transitions to the off state. For this reason, the rise of the gate voltage of the SiC-MOSFET 22 is limited and does not rise to the potential VCC.

As a result, the gate voltage of the SiC-MOSFET 22 decreases, which may lead to deterioration of DC characteristics (and a decrease in energization capability).

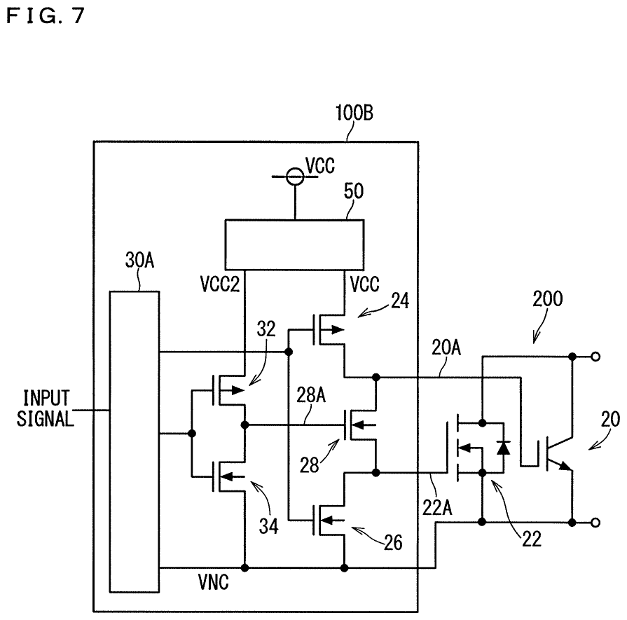

FIG. 7 is a diagram conceptually illustrating a modification of a circuit configuration of a semiconductor device according to the present preferred embodiment. As illustrated in FIG. 7, the semiconductor device includes: a Si-IGBT 20; a parallel connection circuit 200 to which the SiC-MOSFET 22 is connected in parallel; a source MOSFET 24 connected between a gate terminal 20A for on/off control of the Si element and a potential VCC; a sink MOSFET 26 connected between a gate terminal 22A for on/off control of the SiC element and a reference potential VNC; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a source MOSFET 32 connected between a gate terminal 28A for on/off control of the source-sink connection MOSFET 28 and the potential VCC2; a sink MOSFET 34 connected between a gate terminal 28A for on/off control of the source-sink connection MOSFET 28 and a reference potential VNC; a control circuit 30A that performs on/off state transition of the MOSFETs (source MOSFET 24, sink MOSFET 26, source-sink connection MOSFET 28, source MOSFET 32, and sink MOSFET 34) in a predetermined order; an internal power supply circuit 50 that outputs the potential VCC and the potential VCC2. The drive circuit 100B includes a source MOSFET 24, a sink MOSFET 26, a source-sink connection MOSFET 28, a source MOSFET 32, a sink MOSFET 34, a control circuit 30A, and an internal power supply circuit 50. However, it is assumed that the potential VCC2 is higher in voltage than the potential VCC. In addition, the source-sink connection MOSFET 28 is, for example, an N-channel MOSFET.

In the configuration illustrated in FIG. 7, the power supply voltage output from the internal power supply circuit 50 is two systems of the potential VCC and the potential VCC2, and the potential VCC2 is used as a power supply of a circuit (a circuit including the source MOSFET 32 and the sink MOSFET 34) in a preceding stage that applies a gate voltage to the gate terminal 28A for on/off control of the source-sink connection MOSFET 28.

With such a circuit configuration, the source MOSFET 32 functions as an element that charges the gate of the source-sink connection MOSFET 28, and the sink MOSFET 34 functions as an element that discharges the gate of the source-sink connection MOSFET 28, whereby the gate-source voltage VGS of the source-sink connection MOSFET 28 can be secured to be equal to or higher than the threshold voltage even if the gate voltage of the SiC-MOSFET 22 rises. Therefore, the gate of the SiC-MOSFET 22 can be sufficiently charged to suppress deterioration of the DC characteristics.

### Third Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### <Configuration of Semiconductor Device>

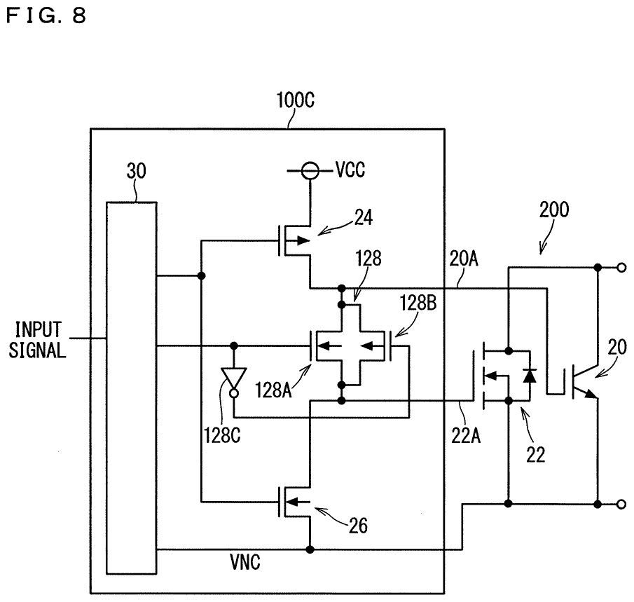

FIG. 8 is a diagram conceptually illustrating an example of a circuit configuration of a semiconductor device according to the present preferred embodiment. As illustrated in FIG. 8, the drive circuit 100C in the semiconductor device includes: a source MOSFET 24 connected between a gate terminal 20A for on/off control of the Si element and a potential VCC; a sink MOSFET 26 connected between a gate terminal 22A for on/off control of the SiC element and a reference potential VNC; a source-sink connection MOSFET 128 that connects gate terminals of both the Si element and the SiC element (that is, connects the gate terminal 20A for on/off control of the Si-IGBT 20 and the gate terminal 22A for on/off control of the SiC-MOSFET 22); and a control circuit 30 that causes these MOSFETs (source MOSFET 24, sink MOSFET 26, and source-sink connection MOSFET 128) to make on/off state transitions in a predetermined order. The parallel connection circuit 200 is connected to the drive circuit 100C.

In the configuration illustrated in FIG. 8, the source-sink connection MOSFET 128 is configured by connecting an N-channel MOSFET 128A and a P-channel MOSFET 128B in parallel. An inverter 128C is connected between the gate terminal of the N-channel MOSFET 128A and the gate terminal of the P-channel MOSFET 128B. In addition, the source-sink connection MOSFET 128 can apply a gate voltage such that both the SiC-MOSFET 22 and the Si-IGBT 20 are turned on or off (that is, the on operation and the off operation are synchronized with each other).

With such a configuration, even in a case where the N-channel MOSFET 128A of the source-sink connection MOSFET 128 is in the off state when the gate voltage of the SiC-MOSFET 22 rises, the P-channel MOSFET 128B can be in the on state. Therefore, since the gate voltage of the SiC-MOSFET 22 can be sufficiently charged without using an additional power supply circuit, deterioration of DC characteristics can be suppressed.

### Fourth Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### <Configuration of Semiconductor Device>

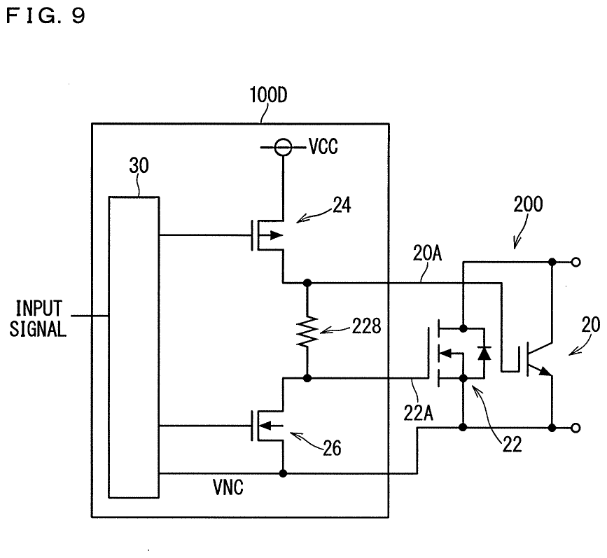

FIG. 9 is a diagram conceptually illustrating an example of a circuit configuration of a semiconductor device according to the present preferred embodiment. As illustrated in FIG. 9, the drive circuit 100D in the semiconductor device includes: a source MOSFET 24 connected between a gate terminal 20A for on/off control of the Si element and a potential VCC; a sink MOSFET 26 connected between a gate terminal 22A for on/off control of the SiC element and a reference potential VNC; a source-sink connection resistor 228 that connects gate terminals of both the Si element and the SiC element (that is, connects the gate terminal 20A for on/off control of the Si-IGBT 20 and the gate terminal 22A for on/off control of the SiC-MOSFET 22); and a control circuit 30 that causes these MOSFETs (source MOSFET 24 and sink MOSFET 26) to make on/off state transitions in a predetermined order. The parallel connection circuit 200 is connected to the drive circuit 100D.

In the configuration shown in FIG. 9, the gate input of the source MOSFET 24 and the gate input of the sink MOSFET 26 are not coordinated, and transition is made from the off state to the on state and from the on state to the off state at individual timings, respectively.

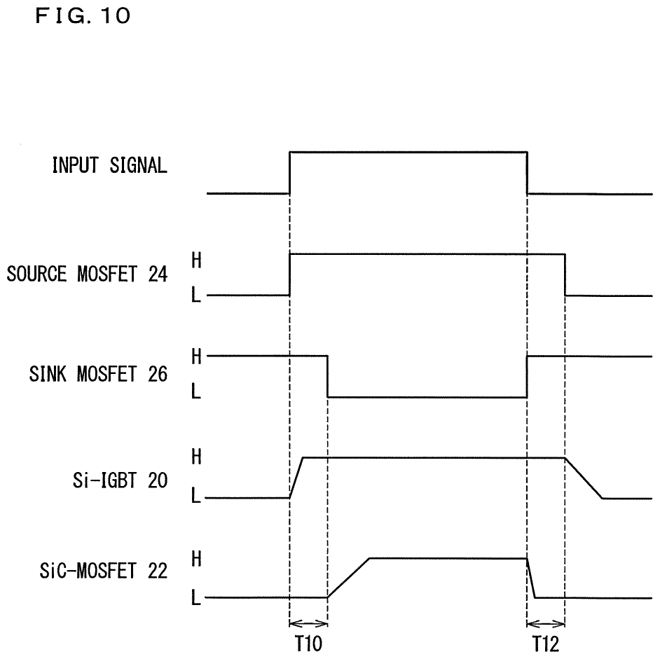

FIG. 10 is a diagram illustrating an example of the operation of the Si element and the operation of the SiC element according to the preferred embodiment.

As illustrated in FIG. 9, when an input signal (on signal) related to the on operation is input to the control circuit 30, the source MOSFET 24 transitions from the off operation to the on operation by the signal input to the gate terminal 24A of the source MOSFET 24 changing from the L level signal to the H level signal. In addition, the signal input to the gate terminal 26A of the sink MOSFET 26 changes from the H-level signal to the L-level signal, so that the sink MOSFET 26 transitions from the on operation to the off operation with a delay of time T10.

As a result, the gate of the Si-IGBT 20 is charged, and the Si-IGBT 20 is turned on before the SiC-MOSFET 22. Thereafter, charging of the gate of the SiC-MOSFET 22 is started, and the SiC-MOSFET 22 is turned on later than the Si-IGBT 20 by the time T10.

Next, when an input signal (off signal) related to the off operation is input to the control circuit 30, the sink MOSFET 26 transitions from the off operation to the on operation by the signal input to the gate terminal 26A of the sink MOSFET 26 changing from the L level signal to the Hlevel signal. In addition, the signal input to the gate terminal 24A of the source MOSFET 24 changes from the H-level signal to the L-level signal, so that the source MOSFET 24 transitions from the on operation to the off operation with a delay of time T12.

As a result, the gate of the SiC-MOSFET 22 is discharged, and the SiC-MOSFET 22 is turned off before the Si-IGBT 20. Thereafter, the discharge of the gate of the Si-IGBT 20 is started, and the Si-IGBT 20 is turned off later than the SiC-MOSFET 22 by the time T12.

With such a configuration, a circuit for driving the source-sink connection MOSFET 28 is unnecessary, and thus the on/off control of the Si-IGBT 20 and the SiC-MOSFET 22 can be performed with a simple configuration.

### Fifth Preferred Embodiment

A semiconductor device according to the present preferred embodiment will be described. Note that, in the following description, constituent elements similar to the constituent elements described in the preferred embodiment described above are denoted 5 by the same reference numerals, and detailed description thereof will be omitted as appropriate.

### <Configuration of Semiconductor Device>

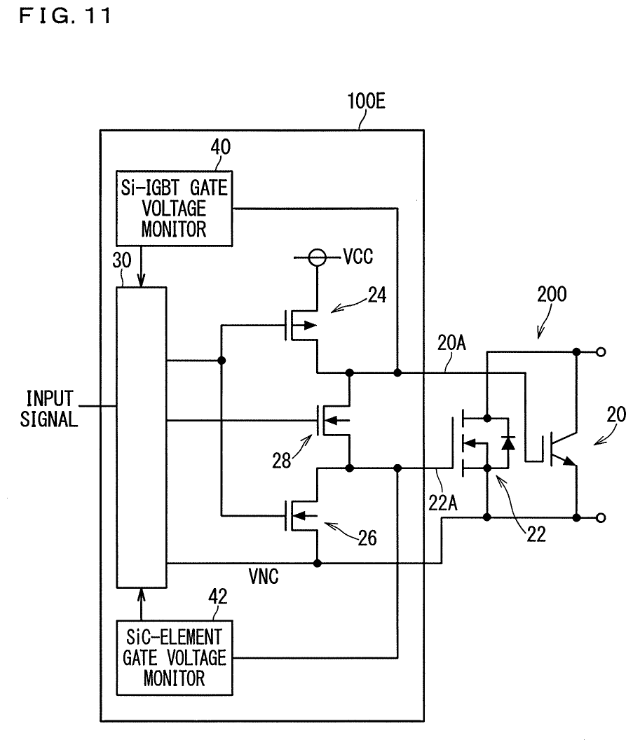

FIG. 11 is a diagram conceptually illustrating an example of a circuit configuration of a semiconductor device according to the present preferred embodiment. As illustrated in FIG. 11, the drive circuit 100E in the semiconductor device includes: a source MOSFET 24 connected between a gate terminal 20A for on/off control of the Si element and a potential VCC; a sink MOSFET 26 connected between a gate terminal 22A for on/off control of the SiC element and a reference potential VNC; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a control circuit 30 that causes these MOSFETs (source MOSFET 24, sink MOSFET 26, and source-sink connection MOSFET 28) to make on/off state transitions in a predetermined order; a Si-IGBT gate voltage monitor 40 that detects a gate voltage of the Si-IGBT 20; and a SiC-MOSFET gate voltage monitor 42 that detects a gate voltage of the SiC-MOSFET 22. The parallel connection circuit 200 is connected to the drive circuit 100E.

In the configuration illustrated in FIG. 11, the control circuit 30 can control the timing of state transition (transition from the on state to the off state or from the off state to the on state) of one of the Si-IGBT 20 and the SiC-MOSFET 22 that makes the state transition later, on the basis of the gate voltage of the Si-IGBT 20 detected by the Si-IGBT gate voltage monitor 40 and the gate voltage of the SiC-MOSFET 22 detected by the SiC-MOSFET gate voltage monitor 42.

In a case where the circuit configuration is not such a circuit configuration, for example, in the on state, the source-sink connection MOSFET 28 is turned off to charge the gate of the Si-IGBT 20, and the Si-IGBT 20 is turned on to start charging the gate of the SiC-MOSFET 22. Therefore, the time setting until the source-sink connection MOSFET 28 is turned on again ensures a certain margin so that the SiC-MOSFET 22 is not turned on before the Si-IGBT 20.

In this case, there is a possibility that the time during which the SiC-MOSFET 22 effective for improving the efficiency is in the on state is shortened.

Therefore, the gate voltage of the Si-IGBT 20 is monitored by the Si-IGBT gate voltage monitor 40, and when the on-operation of the Si-IGBT 20 is confirmed, the source-sink connection MOSFET 28 is immediately transitioned to the on state, so that the gate charging of the SiC-MOSFET 22 is promptly started, whereby the system efficiency can be enhanced.

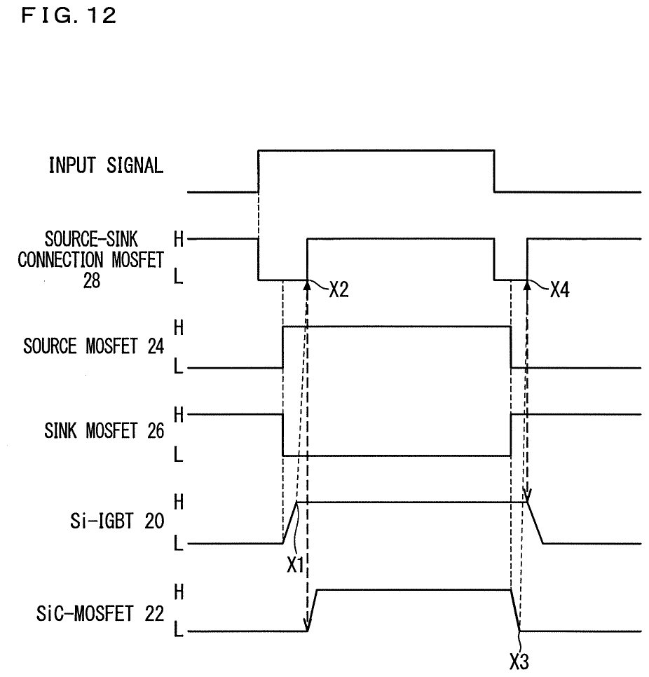

FIG. 12 is a diagram illustrating an example of the operation of the Si element and the operation of the SiC element according to the preferred embodiment.

As illustrated in FIG. 12, the gate voltage of the Si-IGBT 20 is monitored by the Si-IGBT gate voltage monitor 40, and when the off operation of the Si-MOSFET 20 is confirmed (X1), the source-sink connection MOSFET 28 is immediately transitioned to the on state (that is, the time difference between X1 and X2 is minimized), so that the gate charging (on operation) of the SiC-MOSFET 22 can be promptly started.

Similarly, the gate voltage of the SiC-MOSFET 22 is monitored by the SiC-MOSFET gate voltage monitor 42, and when the off operation of the SiC-MOSFET 22 is confirmed (X3), the source-sink connection MOSFET 28 is immediately transitioned to the on state (that is, the time difference between X3 and X4 is minimized), so that the gate discharge (off operation) of the Si-IGBT 20 can be promptly started.

### Sixth Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### <Configuration of Semiconductor Device>

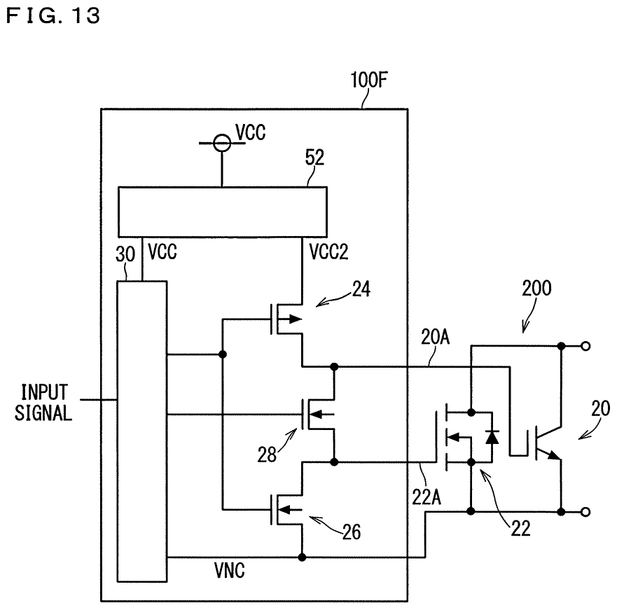

FIG. 13 is a diagram conceptually illustrating an example of a circuit configuration of a semiconductor device according to the present preferred embodiment. As illustrated in FIG. 13, the drive circuit 100F in the semiconductor device includes: a source MOSFET 24 connected between a gate terminal 20A for on/off control of the Si element and a potential VCC2; a sink MOSFET 26 connected between a gate terminal 22A for on/off control of the SiC element and a reference potential VNC; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a control circuit 30 that causes these MOSFETs (source MOSFET 24, sink MOSFET 26, and source-sink connection MOSFET 28) to make on/off state transitions in a predetermined order; and an internal power supply circuit 52 that is connected to the control circuit 30 and the source MOSFET 24 and inputs the potential VCC to the control circuit 30 and the potential VCC2 to the source MOSFET 24. However, the potential VCC2 is assumed to be higher than the potential VCC, and may be the same potential as or different potential from the potential VCC2 illustrated in FIG. 7. A parallel connection circuit 200 is connected to the drive circuit 100F.

In the circuit configuration illustrated in FIG. 3, the gate voltage of the SiC-MOSFET 22 may be lower than the gate voltage of the Si-IGBT 20 by being supplied via the source-sink connection MOSFET 28. Then, DC characteristics may deteriorate, leading to a decrease in operation efficiency.

Therefore, in the configuration illustrated in FIG. 13, it is possible to increase the gate voltage of the SiC-MOSFET 22 by boosting the potential to the potential VCC2 higher than the potential VCC by the internal power supply circuit 52 and then supplying the potential to the source MOSFET 24. Therefore, deterioration of DC characteristics can be suppressed to maintain the operation efficiency.

### Seventh Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### <Configuration of Semiconductor Device>

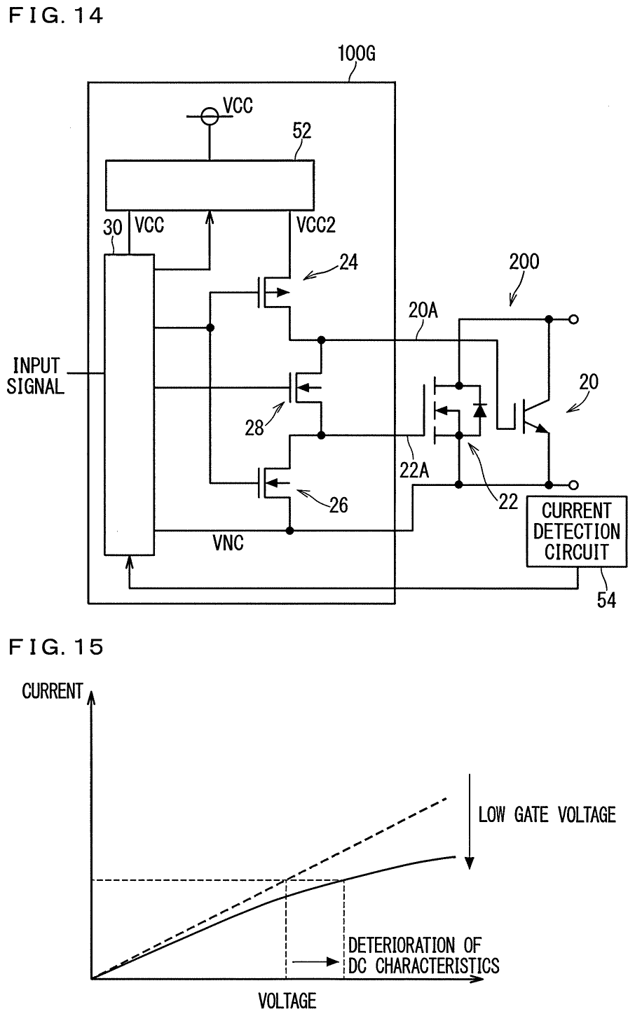

FIG. 14 is a diagram conceptually illustrating an example of a circuit configuration of a semiconductor device according to the present preferred embodiment. As illustrated in FIG. 14, the drive circuit 100G in the semiconductor device includes: a source MOSFET 24 connected between a gate terminal 20A for on/off control of the Si element and a potential VCC2; a sink MOSFET 26 connected between a gate terminal 22A for on/off control of the SiC element and a reference potential VNC; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a control circuit 30 that causes these MOSFETs (source MOSFET 24, sink MOSFET 26, and source-sink connection MOSFET 28) to make on/off state transitions in a predetermined order; and an internal power supply circuit 52 that is connected to the control circuit 30 and the source MOSFET 24 and inputs the potential VCC to the control circuit 30 and the potential VCC2 to the source MOSFET 24; and a current detection circuit 54 that detects a current value at the emitter terminal of the Si-IGBT 20. However, it is assumed that the potential VCC2 is higher in voltage than the potential VCC. A parallel connection circuit 200 is connected to the drive circuit 100G.

The current detection circuit 54 feeds back the detected current value to the control circuit 30. Then, the control circuit 30 may control whether or not the potential VCC is boosted to the potential VCC2 in the internal power supply circuit 52 and input to the source MOSFET 24 on the basis of the magnitude of the current value input from the current detection circuit 54. Specifically, the control circuit 30 may cause the internal power supply circuit 52 to boost the potential VCC to the potential VCC2 and input the potential VCC2 to the source MOSFET 24 only when the magnitude of the current value input from the current detection circuit 54 is larger than a predetermined threshold value.

FIG. 15 is a diagram illustrating an example of DC characteristics of a MOSFET. As illustrated in FIG. 15, as the voltage value increases, the current value significantly decreases (deterioration of DC characteristics is observed).

According to such a configuration, it is possible to maintain the operation efficiency by suppressing deterioration of the DC characteristics while reducing current consumption in the internal power supply circuit 52.

### Eighth Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### <Configuration of Semiconductor Device>

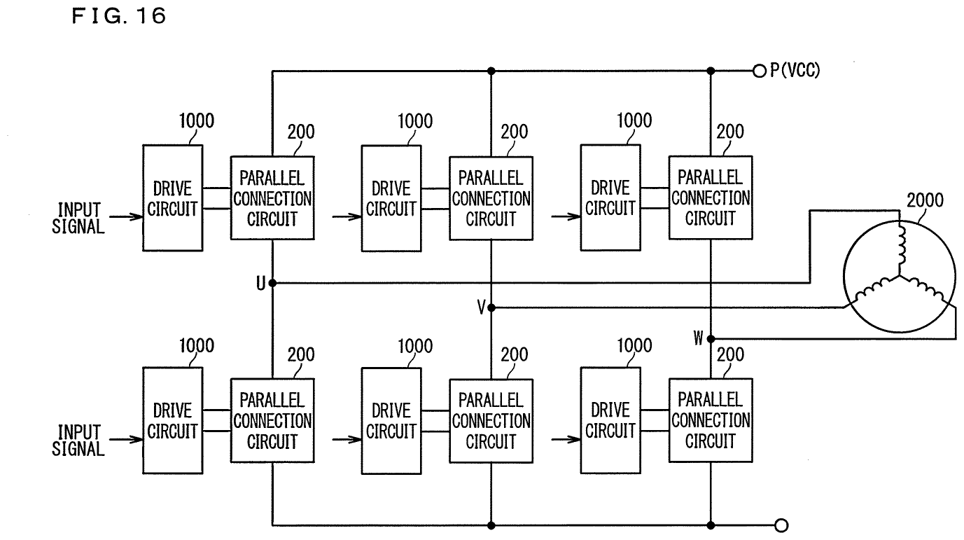

FIG. 16 is a diagram conceptually illustrating an example of a circuit configuration of a semiconductor device according to the present preferred embodiment. The configuration illustrated in FIG. 16 is, for example, a circuit that inverter-drives a motor for rotating a compressor of an air conditioner.

As illustrated in FIG. 16, in the circuit, two parallel connection circuits 200 are connected in series to a load 2000 such as a motor, and a plurality of parallel connection circuits 200 connected in series are further connected in parallel. A drive circuit 1000 that drives a gate is connected to each parallel connection circuit 200. The drive circuit 1000 is, for example, a drive circuit 100A, a drive circuit 100B, a drive circuit 100 C, a drive circuit 100D, a drive circuit 100E, a drive circuit 100F, a drive circuit 100G, or the like.

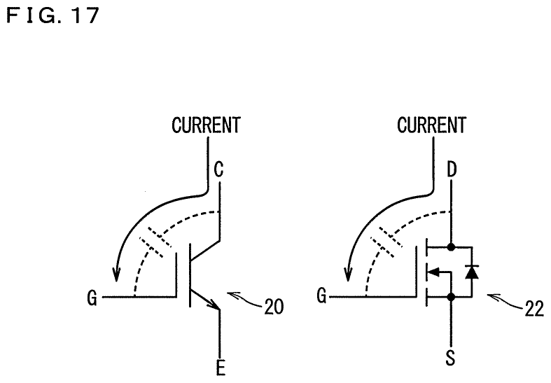

In the circuit as illustrated in FIG. 16, as illustrated in FIG. 17, dv/dt is generated by switching of one of the Si-IGBT 20 and the SiC-MOSFET 22, and the dv/dt may cause a current to flow in the parasitic capacitance between C and G or between D and G of the semiconductor element in the off state. Then, the gate voltage of the semiconductor element in the off state is charged, and there is a possibility that the semiconductor element unintentionally transitions to the on state and enters an abnormal state. Note that FIG. 17 is a diagram illustrating an example of operation of the Si-IGBT 20 and the SiC-MOSFET 22.

In order to prevent such a malfunction, generally, there is a method in which an additional sink MOSFET is disposed in order to reduce the impedance between the gate and the reference potential and quickly draw the current, and the additional sink MOSFET is caused to transition to the on state after the normal off state transition of the semiconductor element.

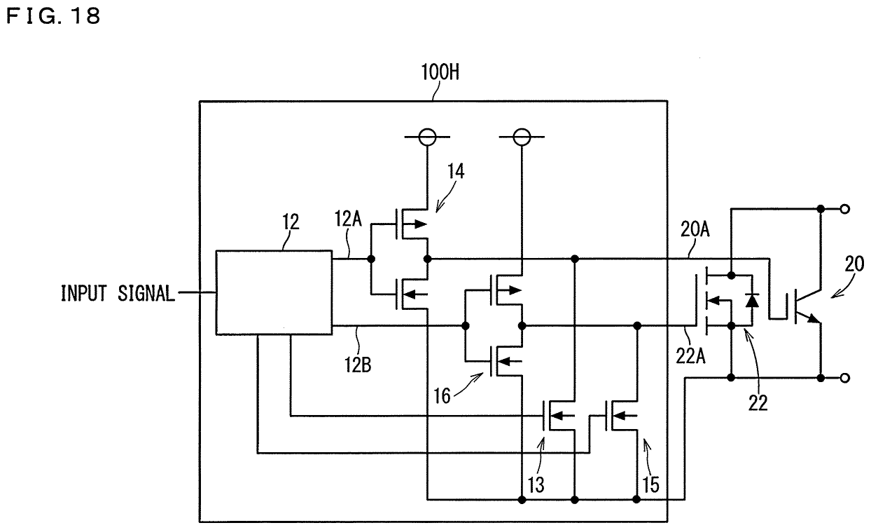

FIG. 18 is a diagram illustrating an example of a drive circuit having a general parallel connection circuit. As shown in the example in FIG. 18, the drive circuit 100H includes: a control signal generation circuit 12 that receives an input signal; a gate drive circuit 14 to which a control signal 12A is input from a control signal generation circuit 12; a gate drive circuit 16 to which a control signal 12B is input from a control signal generation circuit 12; a sink MOSFET 13 connected between a gate terminal 20A and a reference potential VNC; and a sink MOSFET 15 connected between a gate terminal 22A and the reference potential VNC. The Si-IGBT 20 to which a gate signal is input from the gate drive circuit 14 to the gate terminal 20A and the SiC-MOSFET 22 to which a gate signal is input from the gate drive circuit 16 to the gate terminal 22A are connected to the drive circuit 100H.

In the configuration illustrated in FIG. 18, since the gate drive circuit 14 of the Si-IGBT 20 and the gate drive circuit 16 of the SiC-MOSFET 22 are separated, two additional systems of sink MOSFETs (the sink MOSFET 13 and the sink MOSFET 15) are required. Therefore, the circuit scale increases.

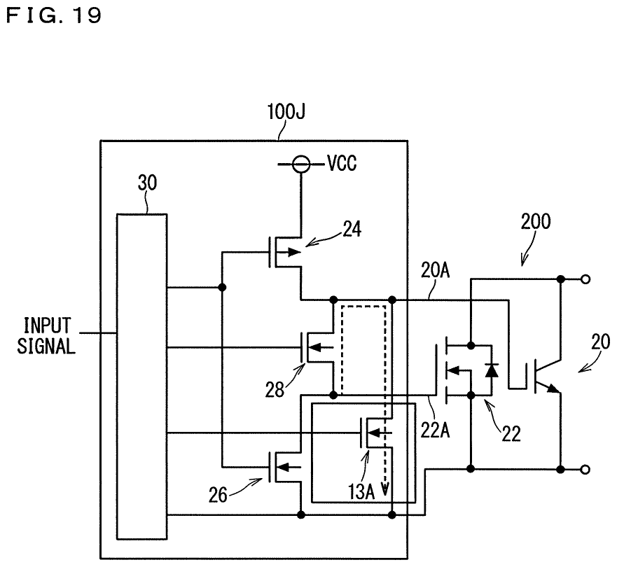

FIG. 19 is a diagram conceptually illustrating an example of a circuit configuration of a semiconductor device according to the present preferred embodiment. As illustrated in FIG. 19, the drive circuit 100J in the semiconductor device includes: a source MOSFET 24 connected between a gate terminal 20A for on/off control of the Si-IGBT 20 and a potential VCC; a sink MOSFET 26 connected between a gate terminal 22A for on/off control of the SiC-MOSFET 22 and a reference potential VNC; a source-sink connection MOSFET 28 that connects gate terminals of both the Si element and the SiC element (that is, connects the gate terminal 20A for on/off control of the Si-IGBT 20 and the gate terminal 22A for on/off control of the SiC-MOSFET 22); a sink MOSFET 13A connected between a gate terminal 20A and a reference potential VNC; and a control circuit 30 that causes these MOSFETs (source MOSFET 24, sink MOSFET 26, source-sink connection MOSFET 28, sink MOSFET 13A) to make on/off state transitions in a predetermined order. The parallel connection circuit 200 is connected to the drive circuit 100J.

According to the configuration illustrated in FIG. 19, since the gate terminal 20A and the gate terminal 22A are connected by the source-sink connection MOSFET 28, the same effect as that in FIG. 18 can be obtained by arranging one additional sink MOSFET 13A in either the gate of the Si-IGBT 20 or the gate of the SiC-MOSFET 22.

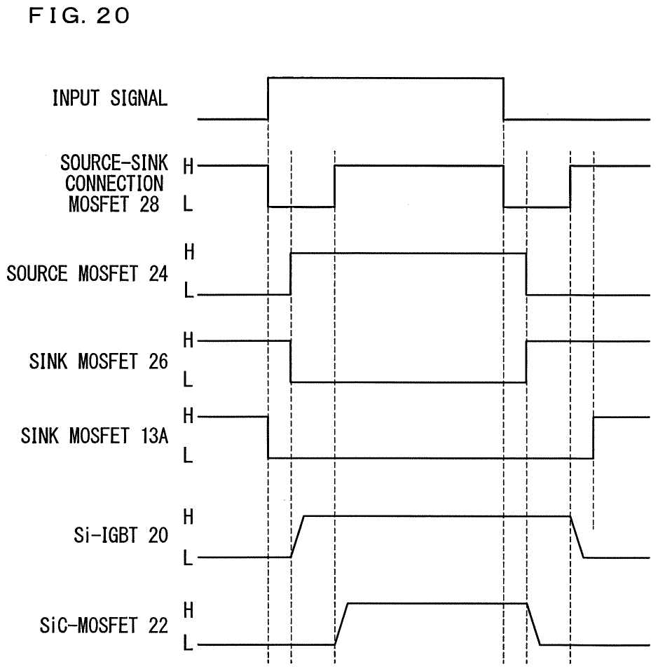

FIG. 20 is a diagram illustrating an example of the operation of the Si element and the operation of the SiC element according to the preferred embodiment.

As illustrated in FIG. 20, the sink MOSFET 13A transitions to the off state when an input signal (on signal) related to the on operation is input to the control circuit 30, and further transitions to the on state after the Si-IGBT 20 transitions to the off state after the input signal (off signal) related to the off operation is input to the control circuit 30. By doing so, the gate potential of the Si-IGBT 20 is held at the reference potential VNC.

### Ninth Preferred Embodiment

A semiconductor device according to the present preferred embodiment will be described. Note that, in the following description, constituent elements similar to the constituent elements described in the preferred embodiment described above are denoted by the same reference numerals, and detailed description thereof will be omitted as appropriate.

### Configuration of Semiconductor Device

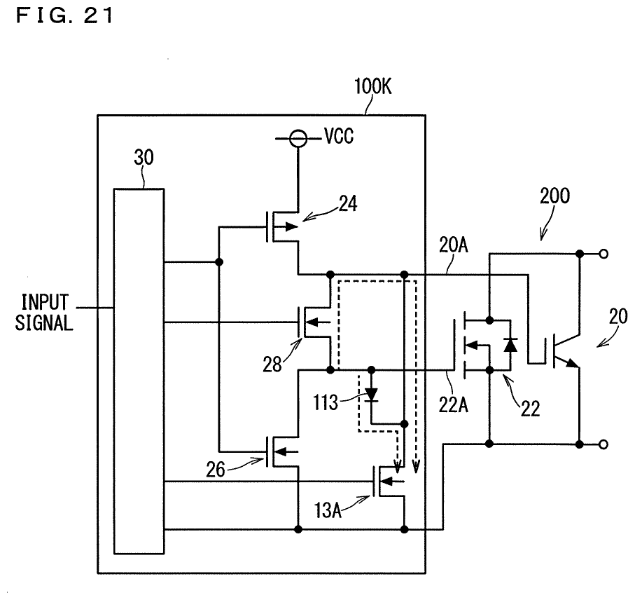

In the configuration illustrated in FIG. 19, the sink MOSFET 13A is connected to the gate of the Si-IGBT 20 that first transitions to the on state. In such a case, the gate of the SiC-MOSFET 22 and the sink MOSFET 13A may be connected via the sink diode. FIG. 21 is a diagram illustrating an example of a configuration in which the gate of the SiC-MOSFET 22 and the sink MOSFET 13A are connected via the sink diode 113. In FIG. 21, the anode of the sink diode 113 is located on the gate side of the SiC-MOSFET 22.

In a case where the sink diode 113 is not provided, since the source-sink connection MOSFET 28 is provided in a path that sinks from the gate of the SiC-MOSFET 22 via the sink MOSFET 13A, there is a possibility that the sink capability is affected.

Therefore, by providing the sink diode 113 and performing the sink in two paths in parallel, the sink capability can be enhanced.

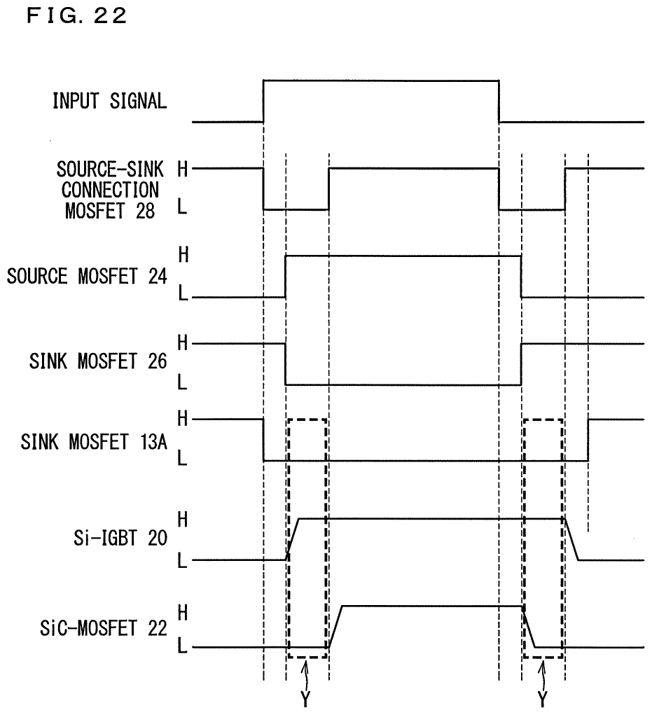

The reason why the sink diode 113 is provided without being directly connected by wiring is to prevent charging of the gate of the SiC-MOSFET 22 to be transitioned to the on state later at that time since the gate of the Si-IGBT 20 to be transitioned to the on state first is charged first as illustrated in the example in FIG. 22. In a case where the sink diode 113 is not provided, the gate of the SiC-MOSFET 22 is charged in the state of Y of FIG. 22. Note that FIG. 22 is a diagram illustrating an example of the operation of the Si element and the operation of the SiC element according to the present preferred embodiment.

### Effects Produced by the Plurality of Preferred Embodiments Described Above

Next, an example of an effect generated by the plurality of preferred embodiments described above will be described. Note that, in the following description, the effects will be described based on the specific configurations exemplified in the plurality of preferred embodiments described above, but may be replaced with other specific configurations exemplified in the present specification as long as similar effects are produced. That is, in the following description, for convenience, only one of the associated specific configurations may be described as a representative, but the specific configuration described as a representative may be replaced with another specific configuration associated.

Furthermore, the replacement may be performed across a plurality of preferred embodiments. That is, the same effect may be produced by combining the respective configurations exemplified in different embodiments.

According to the preferred embodiment described above, a semiconductor device includes a first semiconductor element, a second semiconductor element, a first source semiconductor element, a first sink semiconductor element, a source-sink connection semiconductor element, and a control circuit 30. Here, the first semiconductor element corresponds to, for example, the Si-IGBT 20. The second semiconductor element corresponds to, for example, the SiC-MOSFET 22. The first source semiconductor element corresponds to, for example, the source MOSFET 24. Further, the first sink semiconductor element corresponds to, for example, the sink MOSFET 26. Further, the source-sink connection semiconductor element corresponds to, for example, the source-sink connection MOSFET 28, the source-sink connection MOSFET 128, and the like. The SiC-MOSFET 22 is connected in parallel with the Si-IGBT 20. The source MOSFET 24 is connected between the first power supply potential (for example, the potential VCC) and the gate terminal 20A of the Si-IGBT 20. The sink MOSFET 26 is connected between the reference potential VNC and the gate terminal 22A of the SiC-MOSFET 22. The source-sink connection MOSFET 28 is connected between the gate terminal 20A of the Si-IGBT 20 and the gate terminal 22A of the SiC-MOSFET 22. The control circuit 30 controls the on/off state transition of the source MOSFET 24, the sink MOSFET 26, and the source-sink connection MOSFET 28 such that the Si-IGBT 20 and the SiC-MOSFET 22 are caused to transition to the on state in this order and the SiC-MOSFET 22 and the Si-IGBT 20 are caused to transition to the off state in this order.

According to such a configuration, the transition of the on/off state of each of the Si element and the SiC element can be controlled by a simple circuit configuration including the source-sink connection semiconductor element.

Note that, even in a case where another configuration exemplified in the present specification is appropriately added to the above configuration, that is, even in a case where another configuration not mentioned as the above configuration in the present specification is appropriately added, a similar effect can be generated.

Furthermore, according to the preferred embodiment described above, the control circuit 30 causes the Si-IGBT 20 to transition to the on state by turning off the source-sink connection MOSFET 28, and then causes the SiC-MOSFET 22 to transition to the on state by turning on the source-sink connection MOSFET 28. In addition, the control circuit 30 causes the SiC-MOSFET 22 to transition to the off state by turning off the source-sink connection MOSFET 28, and then causes the SiC-MOSFET 22 to transition to the off state by turning on the source-sink connection MOSFET 28. According to such a configuration, the transition of the on/off state of each of the Si element and the SiC element can be controlled by a simple circuit configuration including the source-sink connection semiconductor element. Specifically, it is possible to perform control to cause a delay in the on/off operation of the Si element and the SiC element with a simple circuit configuration without providing a gate drive circuit for causing a delay in the on/off operation for each of the Si element and the SiC element.

Furthermore, according to the preferred embodiment described above, the semiconductor device includes the second source semiconductor element and the second sink semiconductor element. Here, the second source semiconductor element corresponds to, for example, the source MOSFET 32. Further, the second sink semiconductor element corresponds to, for example, the sink MOSFET 34. The source MOSFET 32 is connected to the gate terminal 28A of the source-sink connection MOSFET 28. The source MOSFET 32 charges the gate of the source-sink connection MOSFET 28. The sink MOSFET 34 is connected to the gate terminal 28A of the source-sink connection MOSFET 28. Further, the sink MOSFET 34 discharges the gate of the source-sink connection MOSFET 28. The source-sink connection MOSFET 28 is an N-channel MOSFET. In addition, the source-sink connection MOSFET 28 is connected to the potential VCC via the source MOSFET 24. In addition, the source-sink connection MOSFET 28 is connected to the second power supply potential (for example, the potential VCC2), which is a potential higher than the potential VCC, via the source MOSFET 32. According to such a configuration, even in a case where the source-sink connection semiconductor element is an N-channel MOSFET, the gate voltage of the SiC-MOSFET 22 can be charged to the potential VCC, so that it is possible to suppress the gate voltage of the SiC-MOSFET 22 from becoming insufficient and to suppress deterioration of the DC characteristics.

In addition, according to the preferred embodiment described above, the source-sink connection MOSFET 128 is an element in which the N-channel MOSFET 128A and the P-channel MOSFET 128B are connected in parallel. Then, the N-channel MOSFET 128A and the P-channel MOSFET 128B are connected between the gate terminal 20A of the Si-IGBT 20 and the gate terminal 22A of the SiC-MOSFET 22. In addition, the on state and the off state of the Si-IGBT 20 and the SiC-MOSFET 22 are synchronized with each other. With such a configuration, even in a case where the N-channel MOSFET 128A of the source-sink connection MOSFET 128 is in the off state when the gate voltage of the SiC-MOSFET 22 rises, the P-channel MOSFET 128B can be in the on state. Therefore, since the gate voltage of the SiC-MOSFET 22 can be sufficiently charged without using an additional power supply circuit, deterioration of DC characteristics can be suppressed.

According to the preferred embodiment described above, the semiconductor device includes the first gate voltage detector and the second gate voltage detector. Here, the first gate voltage detector corresponds to, for example, the Si-IGBT gate voltage monitor 40. The second gate voltage detector corresponds to, for example, the SiC-MOSFET gate voltage monitor 42. The Si-IGBT gate voltage monitor 40 detects the gate voltage of the Si-IGBT 20 as a first gate voltage. The SiC-MOSFET gate voltage monitor 42 detects the gate voltage of the SiC-MOSFET 22 as a second gate voltage. Then, the control circuit 30 controls the transition timing of one of the Si-IGBT 20 and the SiC-MOSFET 22 that makes the on/off state transition later on the basis of the first gate voltage and the second gate voltage. According to such a configuration, by immediately transitioning the source-sink connection MOSFET 28 to the on state at the time point (X1) when the on-operation of the Si-IGBT 20 is confirmed, the gate charging of the SiC-MOSFET 22 can be promptly started. In addition, by immediately transitioning the source-sink connection MOSFET 28 to the on state at the time point (X3) when the off operation of the SiC-MOSFET 22 is confirmed, the gate discharge of the Si-IGBT 20 can be promptly started.

In addition, according to the preferred embodiment described above, the semiconductor device includes the internal power supply circuit 52 connected to the potential VCC and capable of outputting the potential VCC2 higher than the potential VCC. The source MOSFET 24 is connected between the internal power supply circuit 52 and the gate terminal 20A of the Si-IGBT 20. According to such a configuration, it is possible to increase the gate voltage of the SiC-MOSFET 22 by boosting the potential to the potential VCC2 higher than the potential VCC in the internal power supply circuit 52 and then supplying the potential to the source MOSFET 24. Therefore, deterioration of DC characteristics can be suppressed to maintain the operation efficiency.

Furthermore, according to the preferred embodiment described above, the semiconductor device includes the current detection circuit 54 that detects the current flowing through the parallel connection circuit 200 including the Si-IGBT 20 and the SiC-MOSFET 22. Then, the control circuit 30 controls whether to output the potential VCC or the potential VCC2 from the internal power supply circuit 52 to the source MOSFET 24 according to the value of the current detected by the current detection circuit 54. According to such a configuration, it is possible to maintain the operation efficiency by suppressing deterioration of the DC characteristics while reducing current consumption in the internal power supply circuit 52.

Furthermore, according to the preferred embodiment described above, the semiconductor device includes the third sink semiconductor element connected between the gate terminal 20A of the Si-IGBT 20 and the reference potential VNC. Here, the third sink semiconductor element corresponds to, for example, the sink MOSFET 13A. Then, the control circuit 30 turns on the sink MOSFET 13A after the off state transition of the Si-IGBT 20, and holds the gate potential of the Si-IGBT 20 at the reference potential VNC. According to such a configuration, since one semiconductor element for holding the gate potential of the Si-IGBT 20 at the reference potential VNC can be provided, it is possible to suppress the expansion of the circuit scale.

Furthermore, according to the preferred embodiment described above, the semiconductor device includes the sink diode 113 connected between the gate terminal 22A of the SiC-MOSFET 22 and the sink MOSFET 13A. According to such a configuration, it is possible to enhance the sink capability for holding the off state.

In addition, according to the preferred embodiment described above, a plurality of parallel connection circuits 200 in which the Si-IGBT 20 and the SiC-MOSFET 22 are connected in parallel are connected in series and in parallel. Then, a drive circuit 1000 including a source MOSFET 24, a sink MOSFET 26, a source-sink connection MOSFET 28, and a control circuit 30 is connected to each parallel connection circuit 200. According to such a configuration, in the semiconductor device including the plurality of parallel connection circuits 200, since the drive circuit 1000 corresponding to each parallel connection circuit 200 has a simple circuit configuration including the source-sink connection semiconductor element, it is possible to effectively control the transition of the on/off state of each of the Si element and the SiC element.

Further, according to the preferred embodiment described above, the semiconductor device includes: a SiC-MOSFET 22 connected in parallel with the Si-IGBT 20 and the Si-IGBT 20; a source MOSFET 24 connected between the potential VCC and the gate terminal 20A of the Si-IGBT 20; a sink MOSFET 26 connected between the reference potential VNC and the gate terminal 22A of the SiC-MOSFET 22; Included are: a source-sink connection resistor 228 connected between a gate terminal 20A of the Si-IGBT 20 and a gate terminal 22A of the SiC-MOSFET 22; and a control circuit 30 that controls on/off state transition of the source MOSFET 24 and the sink MOSFET 26 so that the Si-IGBT 20 and the SiC-MOSFET 22 transition to the on state in this order and the SiC-MOSFET 22 and the Si-IGBT 20 transition to the off state in this order.

According to such a configuration, the transition of the on/off state of each of the Si element and the SiC element can be controlled with a simple configuration without controlling the gate drive of the source-sink connection semiconductor element.

Further, according to the preferred embodiment described above, the gate terminal of the source MOSFET 24 and the gate terminal of the sink MOSFET 26 are connected to the control circuit 30. According to such a configuration, the gate voltage of the source MOSFET 24 and the gate voltage of the sink MOSFET 26 are controlled, and the transition of the on/off states of the Si-IGBT 20 and the SiC-MOSFET 22 can be controlled.

In addition, according to the preferred embodiment described above, the SiC-MOSFET 22 is a semiconductor element including a wide band gap semiconductor. Then, the allowable current amount of the SiC-MOSFET 22 is lower than the allowable current amount of the Si-IGBT 20. According to such a configuration, by using a semiconductor element made of a wide band gap semiconductor, it is possible to realize cost reduction due to a small size and improvement in efficiency (that is, reduction in loss) due to favorable DC characteristics at the time of low current.

### Modifications of the Plurality of Preferred Embodiments Described Above

In the plurality of preferred embodiments described above, a material, a material, a dimension, a shape, a relative arrangement relationship, an implementation condition, or the like of each component may also be described, but these are one example in all aspects and are not restrictive.

Therefore, innumerable modifications and equivalents in which no examples are shown are assumed within the scope of the technique disclosed in the present specification. For example, a case where at least one component is modified, added, or omitted, and a case where at least one component in at least one embodiment is extracted and combined with a component in another embodiment are included.

In addition, in at least one embodiment described above, in a case where a material name or the like is described without being particularly specified, unless there is a contradiction, the material includes other additives, for example, an alloy or the like.

In addition, as long as no contradiction arises, when it is described in the above-described embodiments that “one” component is provided, “one or more” components may be provided.

Furthermore, each component in the preferred embodiments described above is a conceptual unit, and the scope of the technique disclosed in the present specification includes a case where one component includes a plurality of structures, a case where one component corresponds to a part of a certain structure, and a case where a plurality of components is included in one structure.

In addition, each component in the preferred embodiments described above includes a structure having another structure or shape as long as the same function is exhibited.

In addition, the description herein is referred to for all purposes related to the present technique, and none of them is recognized as prior art.

Hereinafter, aspects of the present disclosure will be collectively described as Appendices.

### (Appendix 1)

A semiconductor device comprising:
a first semiconductor element;
a second semiconductor element connected in parallel to the first semiconductor element;
a first source semiconductor element connected between a first power supply potential and a gate terminal of the first semiconductor element;
a first sink semiconductor element connected between a reference potential and a gate terminal of the second semiconductor element;
a source-sink connection semiconductor element connected between the gate terminal of the first semiconductor element and the gate terminal of the second semiconductor element; and
a control circuit for controlling on/off state transition of the first source semiconductor element, the first sink semiconductor element, and the source-sink connection semiconductor element so as to transition the first semiconductor element and the second semiconductor element to an on state in this order and transition the second semiconductor element and the first semiconductor element to an off state in this order.

### (Appendix 2)

The semiconductor device according to Appendix 1, wherein the control circuit:
causes the first semiconductor element to transition to the on state by turning off the source-sink connection semiconductor element, and then causing the second semiconductor element to transition to the on state by turning on the source-sink connection semiconductor element; and
causes the second semiconductor element to transition to the off state by turning off the source-sink connection semiconductor element, and then causing the second semiconductor element to transition to the off state by turning on the source-sink connection semiconductor element.

### (Appendix 3)

The semiconductor device according to Appendix 1 or 2, further comprising:
a second source semiconductor element that is connected to a gate terminal of the source-sink connection semiconductor element and charges a gate of the source-sink connection semiconductor element; and
a second sink semiconductor element that is connected to the gate terminal of the source-sink connection semiconductor element and discharges the gate of the source-sink connection semiconductor element, wherein
the source-sink connection semiconductor element is an N-channel MOSFET,
connected to the first power supply potential via the first source semiconductor element, and
connected to a second power supply potential higher than the first power supply potential via the second source semiconductor element.

### (Appendix 4)

The semiconductor device according to any one of Appendices 1 to 3, wherein
the source-sink connection semiconductor element is an element in which an N-channel MOSFET and a P-channel MOSFET are connected in parallel,
the N-channel MOSFET and the P-channel MOSFET are connected between the gate terminal of the first semiconductor element and the gate terminal of the second semiconductor element, and
the first semiconductor element and the second semiconductor element are in synchronization with each other in terms of the on state and the off state.

### (Appendix 5)

The semiconductor device according to any one of Appendices 1 to 4, further comprising:
a first gate voltage detector that detects a gate voltage of the first semiconductor element as a first gate voltage; and
a second gate voltage detector that detects a gate voltage of the second semiconductor element as a second gate voltage, wherein
the control circuit controls a transition timing at which one of the first semiconductor element and the second semiconductor element makes the on/off state transition later, based on the first gate voltage and the second gate voltage.

### (Appendix 6)

The semiconductor device according to any one of Appendices 1 to 5, further comprising
an internal power supply circuit that is connected to the first power supply potential and is capable of outputting a second power supply potential higher than the first power supply potential, wherein
the first source semiconductor element is connected between the internal power supply circuit and the gate terminal of the first semiconductor element.

### (Appendix 7)

The semiconductor device according to Appendix 6, further comprising a current detection circuit that detects a current flowing through a parallel connection circuit including the first semiconductor element and the second semiconductor element, wherein
the control circuit controls whether to output the first power supply potential or the second power supply potential from the internal power supply circuit to the first source semiconductor element according to a value of a current detected by the current detection circuit.

### (Appendix 8)

The semiconductor device according to any one of Appendices 1 to 7, further comprising
a third sink semiconductor element connected between the gate terminal of the first semiconductor element and the reference potential, wherein
the control circuit turns on the third sink semiconductor element after the first semiconductor element has transitioned to the off state to retain a gate potential of the first semiconductor element at the reference potential.

### (Appendix 9)

The semiconductor device according to Appendix 8, further comprising a sink diode connected between the gate terminal of the second semiconductor element and the third sink semiconductor element.

### (Appendix 10)

The semiconductor device according to any one of Appendices 1 to 9, wherein
a plurality of parallel connection circuits in which the first semiconductor element and the second semiconductor element are connected in parallel are connected in series and in parallel, and
a drive circuit including the first source semiconductor element, the first sink semiconductor element, the source-sink connection semiconductor element, and the control circuit is connected to each of the parallel connection circuits.

### (Appendix 11)

A semiconductor device comprising:
a first semiconductor element;
a second semiconductor element connected in parallel to the first semiconductor element;
a first source semiconductor element connected between a first power supply potential and a gate terminal of the first semiconductor element;
a first sink semiconductor element connected between a reference potential and a gate terminal of the second semiconductor element;
a source-sink connection resistor connected between the gate terminal of the first semiconductor element and the gate terminal of the second semiconductor element; and
a control circuit for controlling on/off state transition of the first source semiconductor element and the first sink semiconductor element so as to transition the first semiconductor element and the second semiconductor element to an on state in this order and transition the second semiconductor element and the first semiconductor element to an off state in this order.

### (Appendix 12)

The semiconductor device according to any one of Appendices 1 to 11, wherein
a gate terminal of the first source semiconductor element and a gate terminal of the first sink semiconductor element are connected to the control circuit.

### (Appendix 13)

The semiconductor device according to any one of Appendices 1 to 12, wherein
the second semiconductor element is a semiconductor element including a wide band gap semiconductor, and
an allowable current amount of the second semiconductor element is lower than an allowable current amount of the first semiconductor element.

While the disclosure has been shown and described in detail, the foregoing description is in all aspects illustrative and not restrictive. It is therefore understood that numerous modifications and variations can be devised.

What is claimed is:

1. A semiconductor device comprising:
a first semiconductor element;
a second semiconductor element connected in parallel to the first semiconductor element;
a first source semiconductor element connected between a first power supply potential and a gate terminal of the first semiconductor element;
a first sink semiconductor element connected between a reference potential and a gate terminal of the second semiconductor element;
a source-sink connection semiconductor element connected between the gate terminal of the first semiconductor element and the gate terminal of the second semiconductor element; and
a control circuit for controlling on/off state transition of the first source semiconductor element, the first sink semiconductor element, and the source-sink connection semiconductor element so as to transition the first semiconductor element and the second semiconductor element to an on state in this order and transition the second semiconductor element and the first semiconductor element to an off state in this order.

2. The semiconductor device according to claim 1, wherein the control circuit:
causes the first semiconductor element to transition to the on state by turning off the source-sink connection semiconductor element, and then causing the second semiconductor element to transition to the on state by turning on the source-sink connection semiconductor element; and
causes the second semiconductor element to transition to the off state by turning off the source-sink connection semiconductor element, and then causing the second semiconductor element to transition to the off state by turning on the source-sink connection semiconductor element.

3. The semiconductor device according to claim 1, further comprising:
a second source semiconductor element that is connected to a gate terminal of the source-sink connection semiconductor element and charges a gate of the source-sink connection semiconductor element; and
a second sink semiconductor element that is connected to the gate terminal of the source-sink connection semiconductor element and discharges the gate of the source-sink connection semiconductor element, wherein
the source-sink connection semiconductor element is an N-channel MOSFET,
connected to the first power supply potential via the first source semiconductor element, and
connected to a second power supply potential higher than the first power supply potential via the second source semiconductor element.

4. The semiconductor device according to claim 1, wherein
the source-sink connection semiconductor element is an element in which an N-channel MOSFET and a P-channel MOSFET are connected in parallel,
the N-channel MOSFET and the P-channel MOSFET are connected between the gate terminal of the first semiconductor element and the gate terminal of the second semiconductor element, and
the first semiconductor element and the second semiconductor element are in synchronization with each other in terms of the on state and the off state.

5. The semiconductor device according to claim 1, further comprising:
a first gate voltage detector that detects a gate voltage of the first semiconductor element as a first gate voltage; and
a second gate voltage detector that detects a gate voltage of the second semiconductor element as a second gate voltage, wherein
the control circuit controls a transition timing at which one of the first semiconductor element and the second semiconductor element makes the on/off state transition later, based on the first gate voltage and the second gate voltage.

6. The semiconductor device according to claim 1, further comprising
an internal power supply circuit that is connected to the first power supply potential and is capable of outputting a second power supply potential higher than the first power supply potential, wherein
the first source semiconductor element is connected between the internal power supply circuit and the gate terminal of the first semiconductor element.

7. The semiconductor device according to claim 6, further comprising a current detection circuit that detects a current flowing through a parallel connection circuit including the first semiconductor element and the second semiconductor element, wherein
the control circuit controls whether to output the first power supply potential or the second power supply potential from the internal power supply circuit to the first source semiconductor element according to a value of a current detected by the current detection circuit.

8. The semiconductor device according to claim 1, further comprising
a third sink semiconductor element connected between the gate terminal of the first semiconductor element and the reference potential, wherein
the control circuit turns on the third sink semiconductor element after the first semiconductor element has transitioned to the off state to retain a gate potential of the first semiconductor element at the reference potential.

9. The semiconductor device according to claim 8, further comprising a sink diode connected between the gate terminal of the second semiconductor element and the third sink semiconductor element.

10. The semiconductor device according to claim 1, wherein
a plurality of parallel connection circuits in which the first semiconductor element and the second semiconductor element are connected in parallel are connected in series and in parallel, and
a drive circuit including the first source semiconductor element, the first sink semiconductor element, the source-sink connection semiconductor element, and the control circuit is connected to each of the parallel connection circuits.

11. A semiconductor device comprising:
a first semiconductor element;
a second semiconductor element connected in parallel to the first semiconductor element;
a first source semiconductor element connected between a first power supply potential and a gate terminal of the first semiconductor element;
a first sink semiconductor element connected between a reference potential and a gate terminal of the second semiconductor element;
a source-sink connection resistor connected between the gate terminal of the first semiconductor element and the gate terminal of the second semiconductor element; and
a control circuit for controlling on/off state transition of the first source semiconductor element and the first sink semiconductor element so as to transition the first semiconductor element and the second semiconductor element to an on state in this order and transition the second semiconductor element and the first semiconductor element to an off state in this order.

12. The semiconductor device according to claim 1, wherein
a gate terminal of the first source semiconductor element and a gate terminal of the first sink semiconductor element are connected to the control circuit.

13. The semiconductor device according to claim 1, wherein
the second semiconductor element is a semiconductor element including a wide band gap semiconductor, and
an allowable current amount of the second semiconductor element is lower than an allowable current amount of the first semiconductor element.
